(19) United States
(12) Patent Application Publication
(10) Pub. No.: US 2010/0244223 A1
(43) Pub. Date: Sep. 30, 2010

(54) INTEGRATED CIRCUIT PACKAGING SYSTEM WITH AN INTEGRAL-INTERPOSER-STRUCTURE AND METHOD OF MANUFACTURE THEREOF

(76) Inventors: NamJu Cho, Uiwang-si (KR); HeeJo Chi, Ichon si (KR); HanGil Shin, Seongnam-si (KR)

Correspondence Address: LAW OFFICES OF MIKIO ISHIMARU, 333 W. EL CAMINO REAL, SUITE 330, SUNNYVALE, CA, 94087, US

(21) Appl. No.: 12/563,368

(22) Filed: Sep. 21, 2009

Related U.S. Application Data
(63) Continuation-in-part of application No. 12/410,945, filed on Mar. 25, 2009.

(51) Int. Cl. H01L 23/52; H01L 21/00

(52) U.S. Cl. 257/690; 438/124; 257/E21.001; 257/E23.141

(57) ABSTRACT

A method of manufacture of an integrated circuit packaging system includes: providing a substrate having a shielding channel through a substrate first side and a substrate second side; mounting a first shielding interconnect to the shielding channel; mounting an integrated circuit over the substrate and adjacent to the first shielding interconnect; attaching a silicon interposer, having an integral-conductive-shield and a via, to the first shielding interconnect with the integral-conductive-shield over the integrated circuit; grounding the shielding channel at the substrate second side; and forming an encapsulation over the substrate covering the integrated circuit and the first shielding interconnect.

### CROSS-REFERENCE TO RELATED APPLICATION

This is a continuation-in-part of co-pending U.S. patent application Ser. No. 12/410,945 filed Mar. 25, 2009, which is assigned to STATS ChipPAC Ltd., and the subject matter thereof is incorporated herein by reference thereto.

### TECHNICAL FIELD

The present invention relates generally to an integrated circuit packaging system, and more particularly to a system for utilizing an integral-interposer-structure in an integrated circuit packaging system.

### BACKGROUND ART

The rapidly growing market for portable electronics devices, e.g. cellular phones, laptop computers, and PDAs, is an integral facet of modern life. The multitude of portable devices represents one of the largest potential market opportunities for next generation packaging. These devices have unique attributes that have significant impacts on manufacturing integration, in that they must be generally small, lightweight, and rich in functionality and they must be produced in high volumes at relatively low cost.

As an extension of the semiconductor industry, the electronics packaging industry has witnessed ever-increasing commercial competitive pressures, along with growing consumer expectations and the diminishing opportunities for meaningful product differentiation in the marketplace.

Packaging, materials engineering, and development are at the very core of these next generation electronics insertion strategies outlined in road maps for development of next generation products. Future electronic systems may be more intelligent, have higher density, use less power, operate at higher speed, and may include mixed technology devices and assembly structures at lower cost than today.

Current packaging suppliers are struggling to accommodate the high-speed computer devices that are projected to exceed one TeraHertz (THz) in the near future. The current technologies, materials, equipment, and structures offer challenges to the basic assembly of these new devices while still not adequately addressing cooling and reliability concerns.

The envelope of technical capability of next level interconnect assemblies are not yet known, and no clear cost effective technology has yet been identified. Beyond the performance requirements of next generation devices, the industry now demands that cost be a primary product differentiator in an attempt to meet profit goals.

As a result, the road maps are driving electronics packaging to precision, ultra miniature form factors, which require automation in order to achieve acceptable yield. These challenges demand not only automation of manufacturing, but also the automation of data flow and information to the production manager and customer.

There have been many approaches to addressing the advanced packaging requirements of microprocessors and portable electronics with successive generations of semiconductors. Many industry road maps have identified significant gaps between the current semiconductor capability and the available supporting electronic packaging technologies. The limitations and issues with current technologies include increasing clock rates, EMI radiation, thermal loads, second level assembly reliability stresses and cost.

As these package systems evolve to incorporate more components with varied environmental needs, the pressure to push the technological envelope becomes increasingly challenging. More significantly, with the ever-increasing complexity, the potential risk of error increases greatly during manufacture.

In view of the ever-increasing commercial competitive pressures, along with growing consumer expectations and the diminishing opportunities for meaningful product differentiation in the marketplace, it is critical that answers be found for these problems. Additionally, the need to reduce costs, reduce production time, improve efficiencies and performance, and meet competitive pressures, adds an even greater urgency to the critical necessity for finding answers to these problems.

Thus, a need remains for smaller footprints and more robust packages and methods for manufacture. Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system including: providing a substrate having a shielding channel through a substrate first side and a substrate second side; mounting a first shielding interconnect to the shielding channel; mounting an integrated circuit over the substrate and adjacent to the first shielding interconnect; attaching a silicon interposer, having an integral-conductive-shield and a via, to the first shielding interconnect with the integral-conductive-shield over the integrated circuit; grounding the shielding channel at the substrate second side; and forming an encapsulation over the substrate covering the integrated circuit and the first shielding interconnect.

The present invention provides an integrated circuit packaging system, including: a substrate having a shielding channel through a substrate first side and a substrate second side with the shielding channel grounded at the substrate second side; a first shielding interconnect mounted to the shielding channel; an integrated circuit mounted over the substrate and adjacent to the first shielding interconnect; a silicon interposer, having an integral-conductive-shield and a via, attached to the first shielding interconnect with the integral-conductive-shield over the integrated circuit; and an encapsulation over the substrate covering the integrated circuit and the first shielding interconnect.

Certain embodiments of the invention have other steps or elements in addition to or in place of those mentioned above. The steps or element will become apparent to those skilled in the art from a reading of the following detailed description when taken with reference to the accompanying drawings.

### BRIEF DESCRIPTION OF THE DRAWINGS

FIG. 1 is a top view of an integrated circuit packaging system in an embodiment of the present invention.

FIG. 2 is a cross-sectional view of the integrated circuit packaging system along the line 2-2 of FIG. 1.

FIGS. 3A-D are bottom views of integral-conductive-shield for an embodiment of the present invention.

FIG. 4 is a cross-sectional view of an integrated circuit packaging system in a further embodiment of the present invention.

FIG. 5 is a cross-sectional view of an integrated circuit packaging system in a further embodiment of the present invention.

FIG. 6 is a cross-sectional view of an integrated circuit packaging system in a further embodiment of the present invention.

FIG. 7 is a cross-sectional view of an integrated circuit packaging system in a further embodiment of the present invention.

FIG. 8 is a cross-sectional view of an integrated circuit packaging system in a further embodiment of the present invention.

FIG. 9 is a cross-sectional view of an integrated circuit packaging system in a further embodiment of the present invention.

FIG. 10 is a cross-sectional view of an integrated circuit packaging system in a further embodiment of the present invention.

FIG. 11 is the integrated circuit packaging system of FIG. 10 in a mounting phase of manufacture.

FIG. 12 is the integrated circuit packaging system of FIG. 10 after a wire-bonding phase of manufacture.

FIGS. 13A-E are cross-sectional views of external electric components for an embodiment of the present invention.

FIG. 14A is the integrated circuit packaging system of FIG. 1.

FIG. 14B is the integrated circuit packaging system of FIG. 4.

FIG. 14C is the integrated circuit packaging system of FIG. 5.

FIG. 14D is the integrated circuit packaging system of FIG. 6.

FIG. 14E is the integrated circuit packaging system of FIG. 7.

FIG. 14F is the integrated circuit packaging system of FIG. 8.

FIG. 14G is the integrated circuit packaging system of FIG. 9.

FIG. 14H is the integrated circuit packaging system of FIG. 10.

FIG. 15A is a diagram of a further embodiment of the present invention.

FIG. 15B is a diagram of a further embodiment of the present invention.

FIG. 16 is a top view of an integrated circuit packaging system in a further embodiment of the present invention.

FIG. 17 is a cross-sectional view of the integrated circuit packaging system along line segment 17-17 of FIG. 16.

FIG. 18 is a top view of an integrated circuit packaging system in a further embodiment of the present invention.

FIG. 19 is a cross-sectional view of the integrated circuit packaging system along line segment 19-19 of FIG. 18.

FIG. 20 is a top view of an integrated circuit packaging system in a further embodiment of the present invention.

FIG. 21 is a cross-sectional view of the integrated circuit packaging system along line segment 21-21 of FIG. 20.

FIG. 22 is a cross-sectional view of an integrated circuit packaging system along line segment 21-21 of FIG. 20 in a further embodiment of the present invention.

FIG. 23 is a flow chart of a method of manufacture of an integrated circuit packaging system in a further embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

For expository purposes, the term “horizontal” as used herein is defined as a plane parallel to the plane or surface of the substrate, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures. The term “on” means that there is direct contact between elements.

The term “processing” as used herein includes deposition of material or photoresist, patterning, exposure, development, etching, cleaning, and/or removal of the material or photoresist as required in forming a described structure.

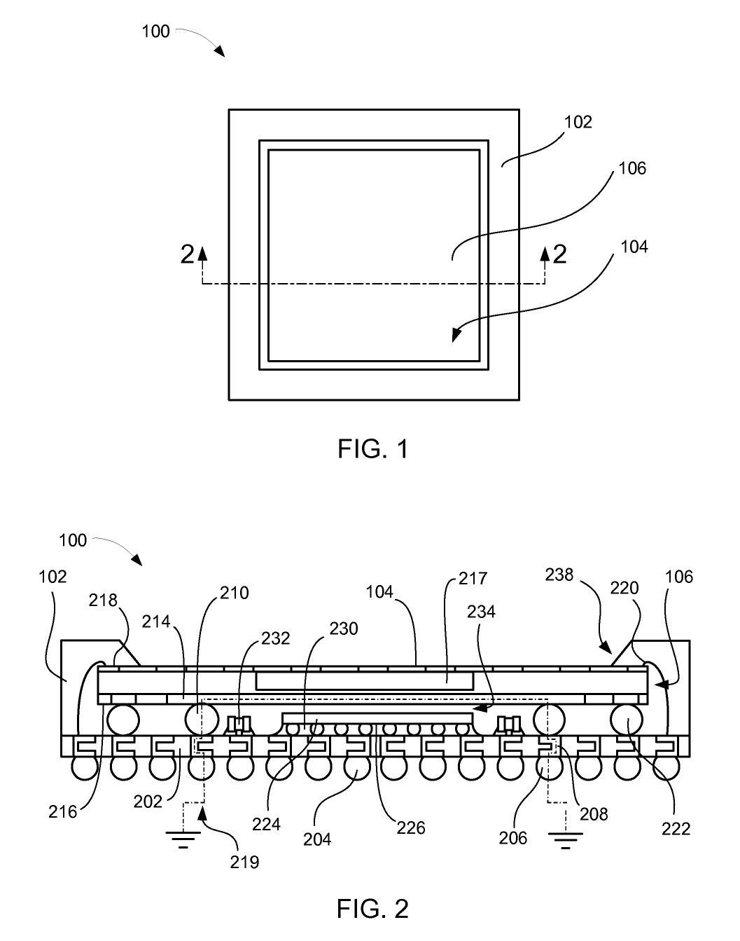

Referring now to FIG. 1, therein is shown a top view of an integrated circuit packaging system 100 in an embodiment of the present invention. The integrated circuit packaging system 100 is shown having an encapsulation 102 surrounding an exposed portion 104 of a structure such as an interposer 106.

Referring now to FIG. 2, therein is shown a cross-sectional view of the integrated circuit packaging system 100 along the line 2-2 of FIG. 1. The integrated circuit packaging system 100 is shown having a substrate 202 such as a laminated plastic or ceramic substrate.

Below the substrate 202 are first external interconnects such as solder bumps 204. Below the substrate 202 second external interconnects 206 such as solder bumps are also mounted. The second external interconnects 206 are connected to the substrate 202 and to substrate-interconnects 208 within the substrate.

The substrate-interconnects 208 electrically connect the second external interconnects 206 through the substrate 202 to first internal interconnects 210, such as solder pillars, mounted above the substrate 202.

Mounted above the first internal interconnects 210 is the interposer 106. The interposer 106 is typically a UV stabilized woven glass and epoxy resin with etched copper conductive pathways and acts as an interfacing structure when other electronic components are mounted externally.

The interposer 106 has an integral-interposer-structure such as an integral-conductive-shield 214 such as a copper sheet attached to a bottom surface 216 of the interposer 106. Similarly the interposer 106 has an embedded die 217 embedded in the interposer 106 between a top surface 218 and the bottom surface 216 of the interposer 106. The embedded die 217 may be connected either to the top surface 218 of the interposer 106, the bottom surface 216 of the interposer 106, or both.

The integral-conductive-shield 214 is integral to the interposer 106 because the integral-conductive-shield 214 is formed along with the bottom surface 216 of the interposer 106. The integral-conductive-shield 214 is attached to the first internal interconnects 210. This provides a grounding path 219 from the integral-conductive-shield 214 through the first internal interconnects 210, the substrate-interconnects 208, and the second external interconnects 206.

The grounding path 219 may be connected to ground when incorporated into a larger electronic system. It has been discovered that the integral-conductive-shield 214 provides a very large grounding plane at an intermediate level. This enhances electrical performance of external components mounted to the interposer 106.

It has further been discovered that the grounding path 219 through the first internal interconnects 210 provides a reduced path to ground improving the integral-conductive-shield 214 performance.

The interposer 106 is connected to the substrate 202 from above with second internal interconnects such as bond wires 220 and from below with third internal interconnects such as solder balls 222 which flank the first internal interconnects 210.

Mounted above the substrate 202 and between the first internal interconnects 210 is an integrated circuit 224 such as a flip-chip with an active side 226. The active side 226 of the integrated circuit 224 faces toward the substrate 202 and is connected to the substrate with the solder balls 222.

An underfill 230 fills between the integrated circuit 224 and the substrate 202. The underfill 230 provides extra rigidity and thermal conductivity. Further, mounted above the substrate 202 and between the first internal interconnects 210 are passive components 232 such as resistors, capacitors, or inductors.

The first internal interconnects 210 provides a stand-off-height 234 between the integral-conductive-shield 214 and the integrated circuit 224 by supporting the integral-conductive-shield 214 above the integrated circuit 224.

Encapsulating the integrated circuit 224 and the passive components 232 is the encapsulation 102. The encapsulation 102 has encapsulation risers 238, which rise up from the interposer 106 and encapsulate the bond wires 220 connecting the interposer 106 to the substrate 202. Between the encapsulation risers 238 the exposed portion 104 of the interposer 106 may be connected to external electronic components, not shown.

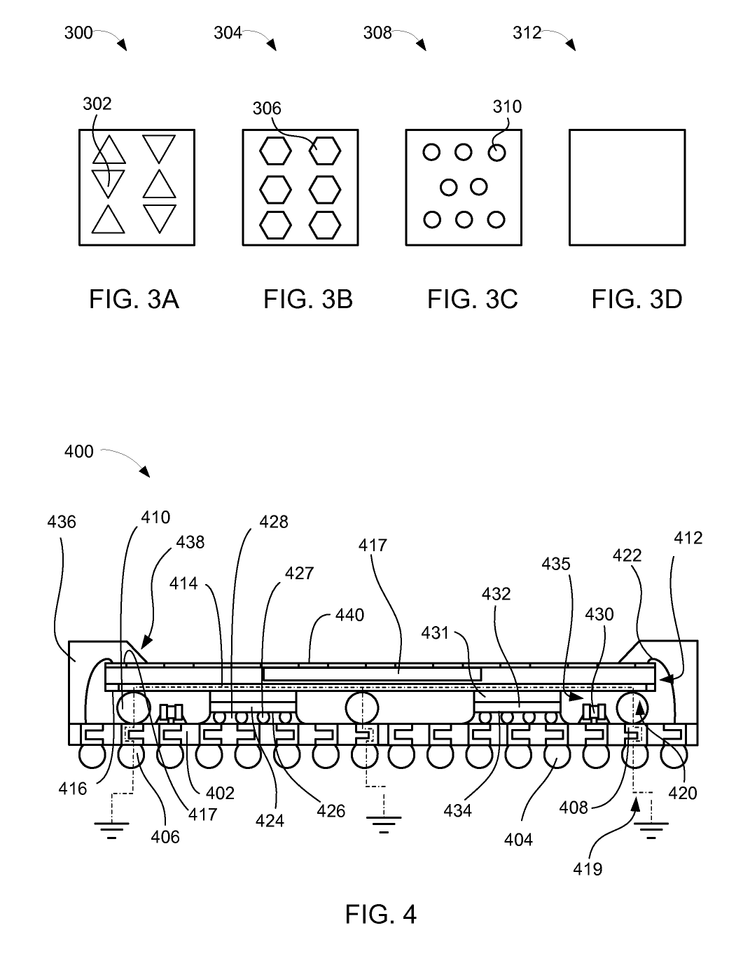

Referring now to FIG. 3A, therein is shown a bottom view of an integral-interposer-structure such as an integral-conductive-shield 300 for an embodiment of the present invention. The integral-conductive-shield 300 is shown with triangular-holes 302. The triangular-holes 302 may be made by etching the integral-conductive-shield 300. The triangular-holes 302 enhance durability by reducing delamination.

Referring now to FIG. 3B, therein is shown a bottom view of an integral-interposer-structure such as an integral-conductive-shield 304 for an embodiment of the present invention. The integral-conductive-shield 304 is shown with hexagonal-holes 306. The hexagonal-holes 306 may be made by etching the integral-conductive-shield 304. The hexagonal-holes 306 enhance durability by reducing delamination.

Referring now to FIG. 3C, therein is shown a bottom view of an integral-interposer-structure such as an integral-conductive-shield 308 for an embodiment of the present invention. The integral-conductive-shield 308 is shown with circular-holes 310. The circular-holes 310 may be made by etching the integral-conductive-shield 308. The circular-holes 310 enhance durability by reducing delamination.

Referring now to FIG. 3D, therein is shown a bottom view of an integral-interposer-structure such as an integral-conductive-shield 312 for an embodiment of the present invention. The integral-conductive-shield 312 is shown as a solid shield. The solid shield has a higher effective shielding capacity.

Referring now to FIG. 4, therein is shown a cross-sectional view of an integrated circuit packaging system 400 in a further embodiment of the present invention. The integrated circuit packaging system 400 is shown having a substrate 402 such as a laminated plastic or ceramic substrate.

Below the substrate 402 are first external interconnects such as solder bumps 404. Below the substrate 402 second external interconnects 406 such as solder bumps are also mounted. The second external interconnects 406 are connected to the substrate 402 and to substrate-interconnects 408 within the substrate.

The substrate-interconnects 408 electrically connect the second external interconnects 406 through the substrate 402 to first internal interconnects 410, such as solder balls, mounted above the substrate 402.

Mounted above the first internal interconnects 410 is a structure such as an interposer 412. The interposer 412 is typically a UV stabilized woven glass and epoxy resin with etched copper conductive pathways and acts as an interfacing structure when other electronic components are mounted externally.

The interposer 412 has an integral-interposer-structure such as an integral-conductive-shield 414 such as a copper sheet attached to a bottom surface 416 of the interposer 412. The integral-conductive-shield 414 is attached to the first internal interconnects 410. This provides a grounding path 419 from the integral-conductive-shield 414 through the first internal interconnects 410, the substrate-interconnects 408, and the second external interconnects 406.

The interposer 412 has an integral-interposer-structure such as an integral-conductive-shield 414 such as a copper sheet attached to a bottom surface 416 of the interposer 412. Similarly the interposer 412 has an embedded die 417 embedded in the interposer 412 between a top surface 418 and the bottom surface 416 of the interposer 412. The embedded die 417 may be connected either to the top surface 418 of the interposer 412, the bottom surface 416 of the interposer 412, or both.

The grounding path 419 may be connected to ground when incorporated into a larger electronic system. It has been discovered that incorporating the integral-conductive-shield 414 into the bottom surface 416 of the interposer 412 substantially reduces costs. First, the process does not require additional shield forming or mounting processes, which decreases the amount of labor required to produce each unit.

Second, the integral-conductive-shield 414 does not require additional material to create an electromagnetic shield because the integral-conductive-shield 414 may be constructed in the interposer 412 using copper layers already used in the formation of the interposer 412. This may be achieved by leaving intact a metal layer forming the integral-conductive-shield 414 instead of selectively etching contact pads.

It has even further been discovered that the first internal interconnects 410 provide additional support under overhangs 420 of the interposer 412 during a wire-bonding phase of manufacture when the interposer 412 is connected to the substrate 402 with second internal interconnects such as bond wires 422.

Mounted above the substrate 402 and between the first internal interconnects 410 is a first integrated circuit 424 such as a flip-chip with an active side 426. The active side 426 of the first integrated circuit 424 faces toward the substrate 402 and is connected to the substrate with third internal interconnects such as solder balls 427. Filling between the first integrated circuit 424 and the substrate 402 is an underfill 428. The underfill 428 provides structural rigidity and thermal conductivity. Further mounted above the substrate 402 and between the first internal interconnects 410 are passive components 430 such as resistors, capacitors, or inductors.

Mounted beside the first integrated circuit 424 and between the first internal interconnects 410 is a second integrated circuit 432 such as a flip-chip with an active side 434. The active side 434 of the second integrated circuit 432 faces toward the substrate 402 and is connected to the substrate 402 with the solder balls 427. Filling between the second integrated circuit 432 and the substrate 402 is the underfill 428.

The first internal interconnects 410 provides a stand-off-height 435 between the integral-conductive-shield 414 and the passive components 430 by supporting the integral-conductive-shield 414 above the passive components 430.

Optionally, the interposer 412 may be attached to the first integrated circuit 424 and to the second integrated circuit 432 with a die attach adhesive 431. Encapsulating the first integrated circuit 424, the second integrated circuit 432, and the bond wires 422 is an encapsulation 436.

The encapsulation 436 has encapsulation risers 438, which rise up from the interposer 412 and encapsulate the bond wires 422. Between the encapsulation risers 438 an exposed portion 440 of the interposer 412 may be connected to external electronic components, not shown.

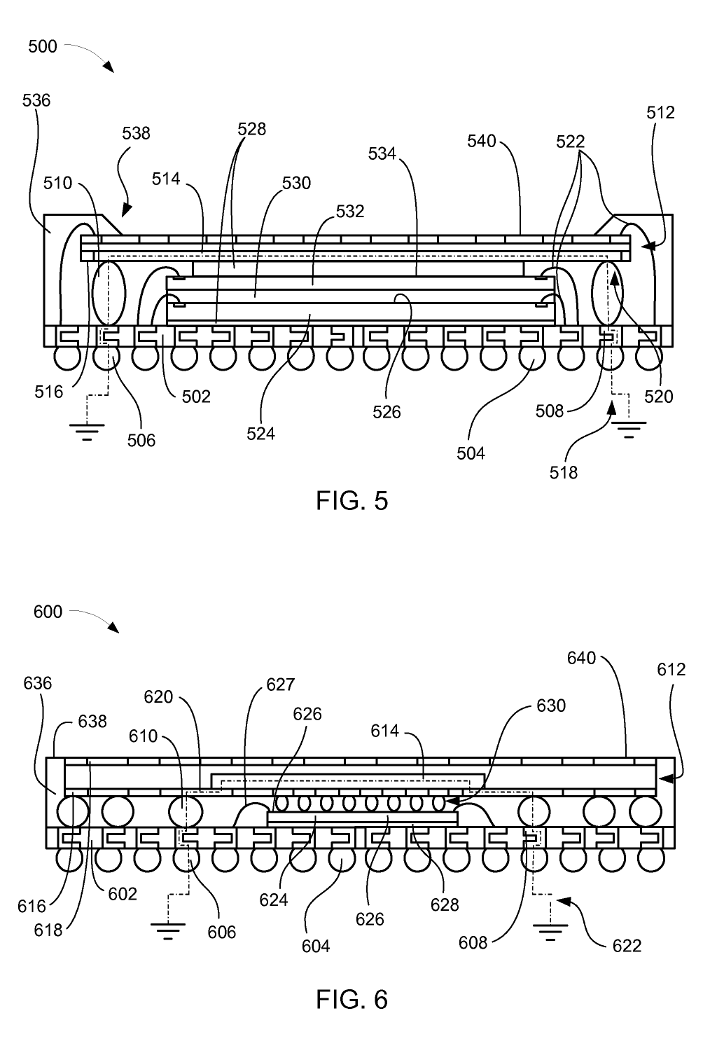

Referring now to FIG. 5, therein is shown a cross-sectional view of an integrated circuit packaging system 500 in a further embodiment of the present invention. The integrated circuit packaging system 500 is shown having a substrate 502 such as a laminated plastic or ceramic substrate.

Below the substrate 502 are first external interconnects such as solder bumps 504. Below the substrate 502 second external interconnects 506 such as solder bumps are also mounted. The second external interconnects 506 are connected to the substrate 502 and to substrate-interconnects 508 within the substrate.

The substrate-interconnects 508 electrically connect the second external interconnects 506 through the substrate 502 to first internal interconnects 510, such as solder pillars, mounted above the substrate 502.

Mounted above the first internal interconnects 510 is a structure such as an interposer 512. The interposer 512 is typically a UV stabilized woven glass and epoxy resin with etched copper conductive pathways and acts as an interfacing structure when other electronic components are mounted externally.

The interposer 512 has an integral-interposer-structure such as an integral-conductive-shield 514 such as a copper sheet attached to a bottom surface 516 of the interposer 512. The integral-conductive-shield 514 is attached to the first internal interconnects 510. This provides a grounding path 518 from the integral-conductive-shield 514 through the first internal interconnects 510, the substrate-interconnects 508, and the second external interconnects 506. The grounding path 518 may be connected to ground when incorporated into a larger electronic system.

It has been discovered that the first internal interconnects 510 provide additional support under overhangs 520 of the interposer 512 during a wire-bonding phase of manufacture when the interposer 512 is connected to the substrate 502 with second internal interconnects such as bond wires 522.

Mounted above the substrate 502 and between the first internal interconnects 510 is a first integrated circuit 524 such as a wire-bonded die with an active side 526. The active side 526 of the first integrated circuit 524 faces away from the substrate 502 and is connected to the substrate with the bond wires 522. The first integrated circuit 524 is attached to the substrate 502 with a die attach adhesive 528.

Applied to the active side 526 of the first integrated circuit 524 is a wire-in-film adhesive 530. The wire-in-film adhesive 530 has a low viscosity and, as temperature increases, the viscosity gets lower. Therefore, the wire-in-film adhesive 530 can be easily pressed over the bond wires 522, above, and around the first integrated circuit 524 and then cured to harden the wire-in-film adhesive 530.

It has been discovered that the wire-in-film adhesive 530 should be a thermally conductive dielectric material. The wire-in-film adhesive 530 can be made of a B-stage material that can be hardened after curing and can maintain a predetermined thickness.

Mounted above the first integrated circuit 524 is a second integrated circuit 532 such as a wire-bonded die with an active side 534. The active side 534 of the second integrated circuit 532 faces away from the substrate 502 and is connected to the substrate 502 with the bond wires 522.

The first internal interconnects 510 provides a stand-off-height 535 between the integral-conductive-shield 514 and the bond wires 522 connecting the active side 534 of the second integrated circuit 532 to the substrate 502 by supporting the integral-conductive-shield 514 above the bond wires 522.

The interposer 512 is connected to the active side 534 of the second integrated circuit 532 with the die attach adhesive 528. Encapsulating the first integrated circuit 524, the second integrated circuit 532, and the bond wires 522 is an encapsulation 536.

The encapsulation 536 has encapsulation risers 538, which rise up from the interposer 512 and encapsulate the bond wires 522 connecting the interposer 512 to the substrate 502. Between the encapsulation risers 538 an exposed portion 540 of the interposer 512 may be connected to external electronic components, not shown.

Referring now to FIG. 6, therein is shown a cross-sectional view of an integrated circuit packaging system 600 in a further embodiment of the present invention. The integrated circuit packaging system 600 is shown having a substrate 602 such as a laminated plastic or ceramic substrate.

Below the substrate 602 are first external interconnects such as solder bumps 604. Below the substrate 602 second external interconnects 606 such as solder bumps are also mounted. The second external interconnects 606 are connected to the substrate 602 and to substrate-interconnects 608 within the substrate.

The substrate-interconnects 608 electrically connect the second external interconnects 606 through the substrate 602 to first internal interconnects 610, such as solder balls, mounted above the substrate 602.

Mounted above the first internal interconnects 610 is a structure such as an interposer 612. The interposer 612 is typically a UV stabilized woven glass and epoxy resin with etched copper conductive pathways and acts as an interfacing structure when other electronic components are mounted externally.

The interposer 612 has an integral-interposer-structure such as an embedded die 614 mounted between a bottom portion 616 and a top portion 618 of the interposer 612. The embedded die 614 is attached to the bottom portion of the interposer 612 and connected to interposer-connection-pads 620. The interposer-connection-pads are connected to the first internal interconnects 610. This provides a connection path 622 from the embedded die 614 through the first internal interconnects 610, the substrate-interconnects 608, and the second external interconnects 606.

The connection path 622 may provide high density low distance connections when incorporated into larger electronic systems. It has been discovered that the incorporation of the embedded die 614 into the interposer 612 provides a reduced package height.

Mounted above the substrate 602 and between the first internal interconnects 610 is an integrated circuit 624 such as a flip-chip with an active side 626. The active side 626 of the integrated circuit 624 faces away from the substrate 602 and is connected to the substrate with second internal interconnects such as bond wires 627.

The integrated circuit 624 is attached to the substrate 602 with a die-attach-adhesive 628. The active side 626 of the integrated circuit 624 is further connected to the interposer 612 with third internal interconnects such as solder balls 630. The interposer 612 is further connected to the substrate 602 with the solder balls 630.

Encapsulating the integrated circuit 624 and the passive components 630 is an encapsulation 636. The encapsulation 636 has a top surface 638, which is level with an exposed portion 640 of the interposer 612. The exposed portion 640 may be connected to external electronic components, not shown.

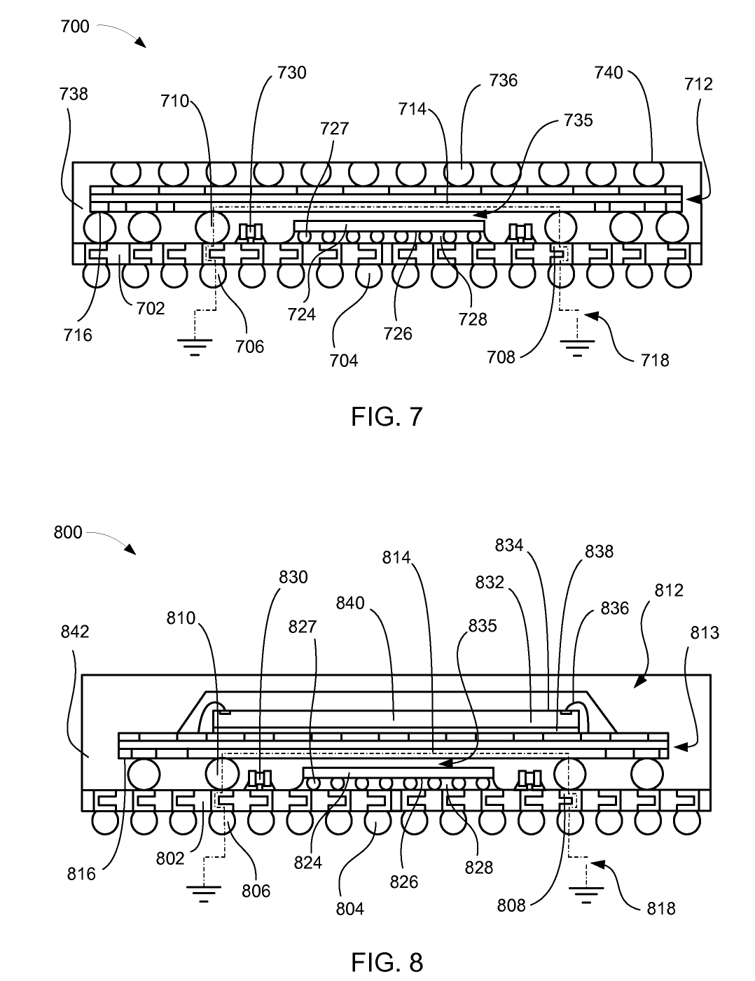

Referring now to FIG. 7, therein is shown a cross-sectional view of an integrated circuit packaging system 700 in a further embodiment of the present invention. The integrated circuit packaging system 700 is shown having a substrate 702 such as a laminated plastic or ceramic substrate.

Below the substrate 702 are first external interconnects such as solder bumps 704. Below the substrate 702 second external interconnects 706 such as solder bumps are also mounted. The second external interconnects 706 are connected to the substrate 702 and to substrate-interconnects 708 within the substrate.

The substrate-interconnects 708 electrically connect the second external interconnects 706 through the substrate 702 to first internal interconnects 710, such as solder balls, mounted above the substrate 702.

Mounted above the first internal interconnects 710 is a structure such as an interposer 712. The interposer 712 is typically a UV stabilized woven glass and epoxy resin with etched copper conductive pathways and acts as an interfacing structure when other electronic components are mounted externally.

The interposer 712 has an integral-interposer-structure such as an integral-conductive-shield 714 such as a copper sheet attached to a bottom surface 716 of the interposer 712. The integral-conductive-shield 714 is attached to the first internal interconnects 710. This provides a grounding path 718 from the integral-conductive-shield 714 through the first internal interconnects 710, the substrate-interconnects 708, and the second external interconnects 706. The grounding path 718 may be connected to ground when incorporated into a larger electronic system.

Mounted above the substrate 702 and between the first internal interconnects 710 is an integrated circuit 724 such as a flip-chip with an active side 726. The active side 726 of the integrated circuit 724 faces toward the substrate 702 and is connected to the substrate with third internal interconnects such as solder balls 727.

An underfill 728 fills between the integrated circuit 724 and the substrate 702. The underfill 728 provides extra rigidity and thermal conductivity. Further, mounted above the substrate 702 and between the first internal interconnects 710 are passive components 730 such as resistors, capacitors, or inductors.

The first internal interconnects 710 provides a stand-off-height 735 between the integral-conductive-shield 714 and the integrated circuit 724 by supporting the integral-conductive-shield 714 above the integrated circuit 724. The interposer 712 is further connected to the substrate 702 with the solder balls 727.

Mounted above the interposer 712 are embedded solder balls 736. An encapsulation 738 partially encapsulates the embedded solder balls 736 leaving exposed portions 740 of the embedded solder balls 736 that may be connected to external electronic components, not shown. The encapsulation 738 also encapsulates the integrated circuit 724 and the passive components 730.

Referring now to FIG. 8, therein is shown a cross-sectional view of an integrated circuit packaging system 800 in a further embodiment of the present invention. The integrated circuit packaging system 800 is shown having a substrate 802 such as a laminated plastic or ceramic substrate.

Below the substrate 802 are first external interconnects such as solder bumps 804. Below the substrate 802 second external interconnects 806 such as solder bumps are also mounted. The second external interconnects 806 are connected to the substrate 802 and to substrate-interconnects 808 within the substrate.

The substrate-interconnects 808 electrically connect the second external interconnects 806 through the substrate 802 to first internal interconnects 810, such as solder balls, mounted above the substrate 802.

Mounted above the first internal interconnects 810 is a structure such as an inner-stacking-module 812 with an inner-stacking-module-substrate 813. The inner-stacking-module-substrate 813 is typically a UV stabilized woven glass and epoxy resin with etched copper conductive pathways.

The inner-stacking-module-substrate 813 has an integral-interposer-structure such as an integral-conductive-shield 814 such as a copper sheet attached to a bottom surface 816 of the inner-stacking-module-substrate 813. The integral-conductive-shield 814 is attached to the first internal interconnects 810. This provides a grounding path 818 from the integral-conductive-shield 814 through the first internal interconnects 810, the substrate-interconnects 808, and the second external interconnects 806. The grounding path 818 may be connected to ground when incorporated into a larger electronic system.

Mounted above the substrate 802 and between the first internal interconnects 810 is an integrated circuit 824 such as a flip-chip with an active side 826. The active side 826 of the integrated circuit 824 faces toward the substrate 802 and is connected to the substrate with second internal interconnects such as solder balls 827.

An underfill 828 fills between the integrated circuit 824 and the substrate 802. The underfill 828 provides extra rigidity and thermal conductivity. Further, mounted above the substrate 802 and between the first internal interconnects 810 are passive components 830 such as resistors, capacitors, or inductors.

The first internal interconnects 810 provides a stand-off-height 835 between the integral-conductive-shield 814 and the integrated circuit 824 by supporting the integral-conductive-shield 814 above the integrated circuit 824. The inner-stacking-module-substrate 813 is further connected to the substrate 802 with the solder balls 827.

Mounted above the inner-stacking-module-substrate 813 is an inner-stacking-module-die 832 such as a wire-bonded die with an active side 834. The active side 834 of the inner-stacking-module-die 832 is connected to the inner-stacking-module-substrate 813 with inner-stacking-module-bond wires 836.

The inner-stacking-module-die 832 is attached to the inner-stacking-module-substrate 813 with an inner-stacking-module-die-attach-adhesive 838. Encapsulating the inner-stacking-module-die 832 is an inner-stacking-module-encapsulation 840. Encapsulating the integrated circuit 824, the passive components 830, and the inner-stacking-module 812 is an encapsulation 842.

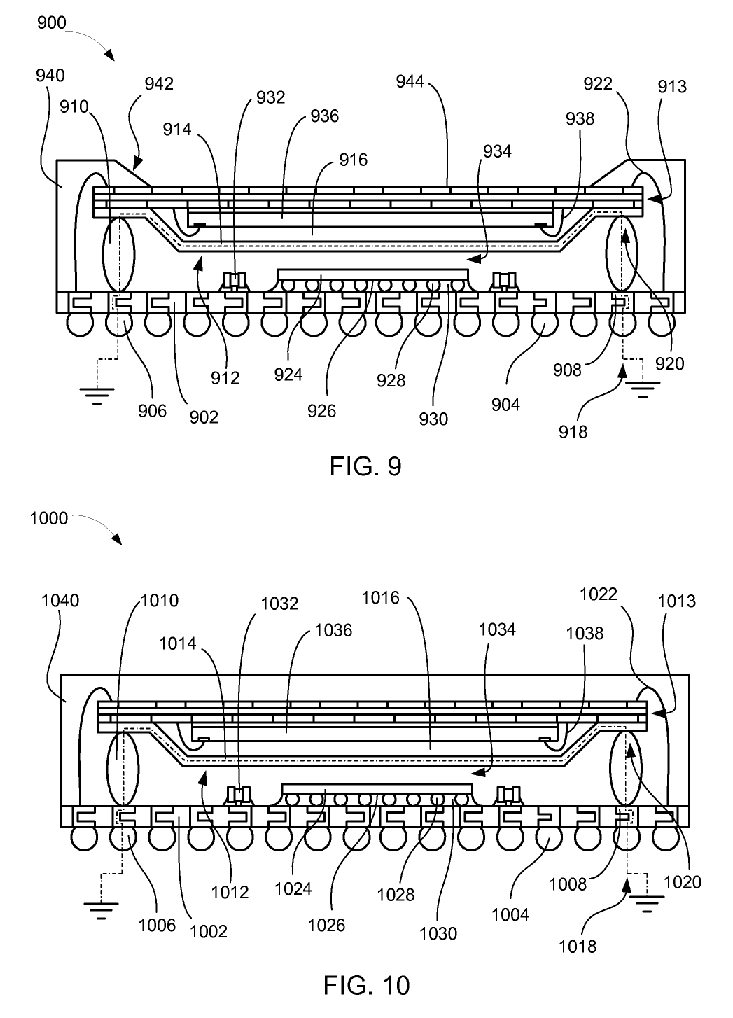

Referring now to FIG. 9, therein is shown a cross-sectional view of an integrated circuit packaging system 900 in a further embodiment of the present invention. The integrated circuit packaging system 900 is shown having a substrate 902 such as a laminated plastic or ceramic substrate.

Below the substrate 902 are first external interconnects such as solder bumps 904. Below the substrate 902 second external interconnects 906 such as solder bumps are also mounted. The second external interconnects 906 are connected to the substrate 902 and to substrate-interconnects 908 within the substrate.

The substrate-interconnects 908 electrically connect the second external interconnects 906 through the substrate 902 to first internal interconnects 910, such as solder pillars, mounted above the substrate 902.

Mounted above the first internal interconnects 910 is a structure such as an inner-stacking-module 912 with an inner-stacking-module-substrate 913. The inner-stacking-module-substrate 913 is typically a UV stabilized woven glass and epoxy resin with etched copper conductive pathways and acts as an interfacing structure when other electronic components are mounted externally.

The inner-stacking-module 912 has an integral-interposer-structure such as an integral-conductive-shield 914 such as a copper sheet coated on an inner-stacking-module-encapsulation 916 and the inner-stacking-module-substrate 913 of the inner-stacking-module 912. The integral-conductive-shield 914 is attached to the first internal interconnects 910. This provides a grounding path 918 from the integral-conductive-shield 914 through the first internal interconnects 910, the substrate-interconnects 908, and the second external interconnects 906.

The grounding path 918 may be connected to ground when incorporated into a larger electronic system.

The integral-conductive-shield 914 coated on the inner-stacking-module-encapsulation 916 also decreases the yield loss risk by using inner-stacking-modules that are already verified as known good inner-stacking-modules.

Mounted above the substrate 902 and between the first internal interconnects 910 is an integrated circuit 924 such as a flip-chip with an active side 926. The active side 926 of the integrated circuit 924 faces toward the substrate 902 and is connected to the substrate with third internal interconnects such as solder balls 928.

An underfill 930 fills between the integrated circuit 924 and the substrate 902. The underfill 930 provides extra rigidity and thermal conductivity. Further, mounted above the substrate 902 and between the first internal interconnects 910 are passive components 932 such as resistors, capacitors, or inductors.

The first internal interconnects 910 provides a stand-off-height 934 between the integral-conductive-shield 914 and the integrated circuit 924 by supporting the integral-conductive-shield 914 above the integrated circuit 924.

The inner-stacking-module-encapsulation 916 encapsulates an inner-stacking-module-die 936 such as a wire-bonded die. The inner-stacking-module-die 936 is connected to the inner-stacking-module-substrate 913 with inner-stacking-module-interconnects 938 such as bond wires.

Encapsulating the integrated circuit 924 and the passive components 932 is an encapsulation 940. The encapsulation 940 has encapsulation risers 942 which rise up from the inner-stacking-module-substrate 913 and encapsulate the bond wires 922 connecting the inner-stacking-module-substrate 913 to the substrate 902. Between the encapsulation risers 942 an exposed portion 944 of the inner-stacking-module-substrate 913 may be connected to external electronic components, not shown.

Referring now to FIG. 10, therein is shown a cross-sectional view of an integrated circuit packaging system 1000 in a further embodiment of the present invention. The integrated circuit packaging system 1000 is shown having a substrate 1002 such as a laminated plastic or ceramic substrate.

Below the substrate 1002 are first external interconnects such as solder bumps 1004. Below the substrate 1002 second external interconnects 1006 such as solder bumps are also mounted. The second external interconnects 1006 are connected to the substrate 1002 and to substrate-interconnects 1008 within the substrate.

The substrate-interconnects 1008 electrically connect the second external interconnects 1006 through the substrate 1002 to first internal interconnects 1010, such as solder pillars, mounted above the substrate 1002.

Mounted above the first internal interconnects 1010 is a structure such as an inner-stacking-module 1012 with an inner-stacking-module-substrate 1013. The inner-stacking-module-substrate 1013 is typically a UV stabilized woven glass and epoxy resin with etched copper conductive pathways and acts as an interfacing structure when other electronic components are mounted externally.

The inner-stacking-module 1012 has an integral-interposer-structure such as an integral-conductive-shield 1014 such as a copper sheet coated on an inner-stacking-module-encapsulation 1016 and the inner-stacking-module-substrate 1013 of the inner-stacking-module 1012. The integral-conductive-shield 1014 is attached to the first internal interconnects 1010. This provides a grounding path 1018 from the integral-conductive-shield 1014 through the first internal interconnects 1010, the substrate-interconnects 1008, and the second external interconnects 1006.

The grounding path 1018 may be connected to ground when incorporated into a larger electronic system.

The integral-conductive-shield 1014 coated on the inner-stacking-module-encapsulation 1016 also decreases the yield loss risk by using inner-stacking-modules that are already verified as known good inner-stacking-modules.

Mounted above the substrate 1002 and between the first internal interconnects 1010 is an integrated circuit 1024 such as a flip-chip with an active side 1026. The active side 1026 of the integrated circuit 1024 faces toward the substrate 1002 and is connected to the substrate with third internal interconnects such as solder balls 1028.

An underfill 1030 fills between the integrated circuit 1024 and the substrate 1002. The underfill 1030 provides extra rigidity and thermal conductivity. Further, mounted above the substrate 1002 and between the first internal interconnects 1010 are passive components 1032 such as resistors, capacitors, or inductors.

The first internal interconnects 1010 provides a stand-off-height 1034 between the integral-conductive-shield 1014 and the integrated circuit 1024 by supporting the integral-conductive-shield 1014 above the integrated circuit 1024.

The inner-stacking-module-encapsulation 1016 encapsulates an inner-stacking-module-die 1036 such as a wire-bonded die. The inner-stacking-module-die 1036 is connected to the inner-stacking-module-substrate 1013 with inner-stacking-module-interconnects 1038 such as bond wires.

Encapsulating the integrated circuit 1024 and the passive components 1032 is an encapsulation 1040. The encapsulation 1040 may fully encapsulate the inner-stacking-module 1012.

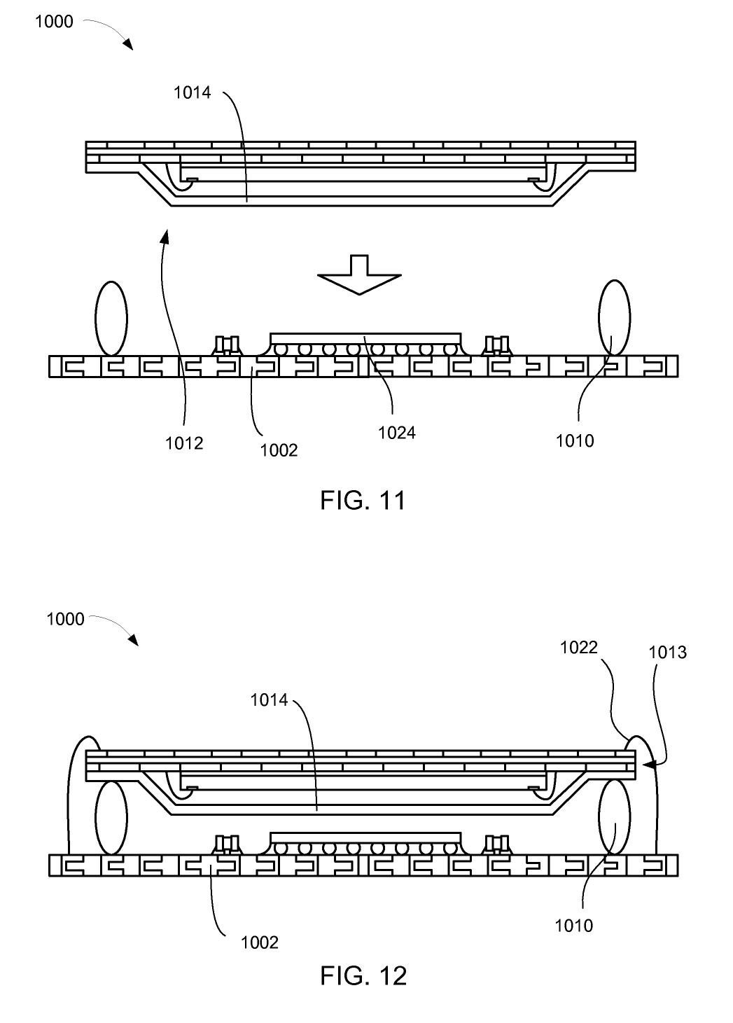

Referring now to FIG. 11, therein is shown the integrated circuit packaging system 1000 of FIG. 10 in a mounting phase of manufacture. The integrated circuit packaging system 1000 is shown having the inner-stacking-module 1012 mounted over the integrated circuit 1024, the first internal interconnects 1010, and the substrate 1002.

The integral-conductive-shield 1014 is integral to the inner-stacking-module 1012 because it is fabricated with the inner-stacking-module 1012 before it is mounted above the substrate 1002.

Referring now to FIG. 12, therein is shown the integrated circuit packaging system 1000 of FIG. 10 after a wire-bonding phase of manufacture. The integrated circuit packaging system 1000 is shown having the integral-conductive-shield 1014 connected to the first internal interconnects 1010 and the bond wires 1022 connecting the inner-stacking-module-substrate 1013 to the substrate 1002.

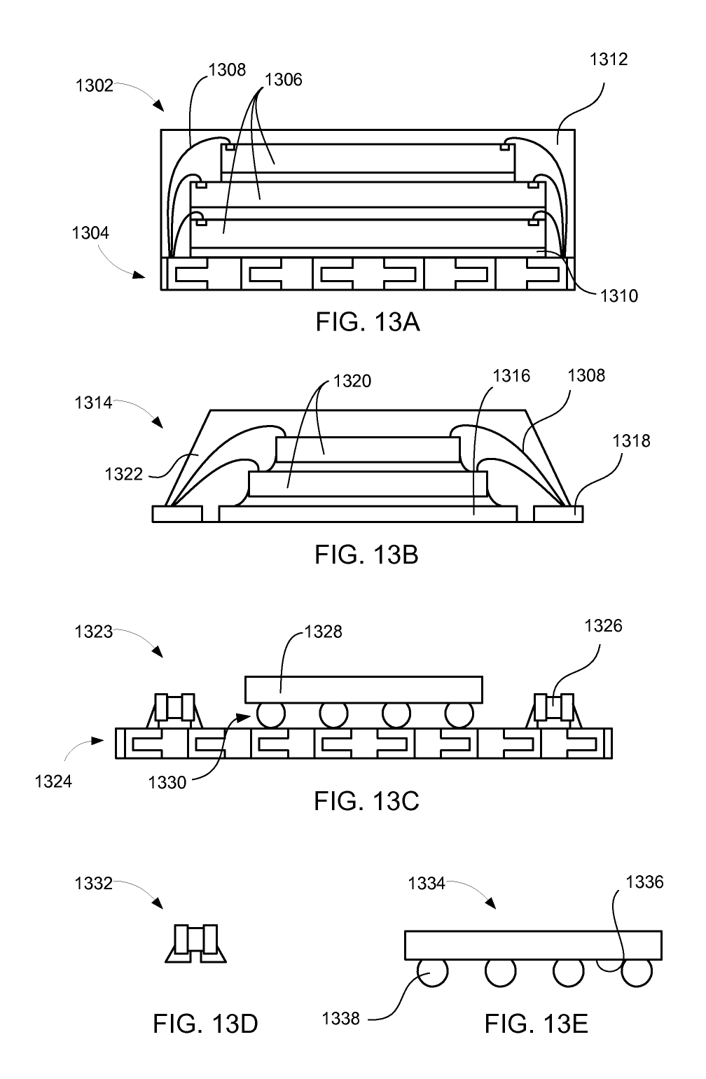

Referring now to FIG. 13A, therein is shown a cross-sectional view of an external electric component for an embodiment of the present invention such as an array package 1302 having a substrate 1304 with multiple-integrated-circuit-dies 1306 stacked above the substrate 1304. The multiple-integrated-circuit-dies 1306 are connected to the substrate 1304 with interconnects such as bond wires 1308. The multiple-integrated-circuit-dies 1306 are attached with a die attach adhesive 1310. An encapsulation 1312 such as a film assisted molding encapsulates the multiple-integrated-circuit-dies 1306 and the bond wires 1308.

Referring now to FIG. 13B, therein is shown a cross-sectional view of an external electric component for an embodiment of the present invention such as a quad-flatpak package 1314 having a die pad 1316 and bond-fingers 1318. Stacked above the die pad 1316 are multiple-integrated-circuit-dies 1320 attached with the die attach adhesive 1310. The multiple-integrated-circuit-dies 1320 are connected to the bond fingers 1318 with the bond wires 1308. The multiple-integrated-circuit-dies 1320 and the bond wires 1308 are encapsulated in an encapsulation 1322 such as a film assisted molding.

Referring now to FIG. 13C, therein is shown a cross-sectional view of an external electric component for an embodiment of the present invention such as a compound circuit 1323 having a substrate 1324. Above the substrate 1324 passive components 1326 such as resistors, capacitors, and inductors are mounted peripheral to an integrated circuit 1328 such as a flip chip. The integrated circuit 1328 is connected to the substrate 1324 with interconnects such as solder bumps 1330.

Referring now to FIG. 13D, therein is shown a cross-sectional view of an external electric component for an embodiment of the present invention such as a passive component 1332 such as a resistor, capacitor, or inductor.

Referring now to FIG. 13E, therein is shown a cross-sectional view of an external electric component for an embodiment of the present invention such as an integrated circuit die 1334 such as a flip chip. The integrated circuit die 1334 is shown having an active side 1336 with interconnects 1338 such as solder bumps mounted below.

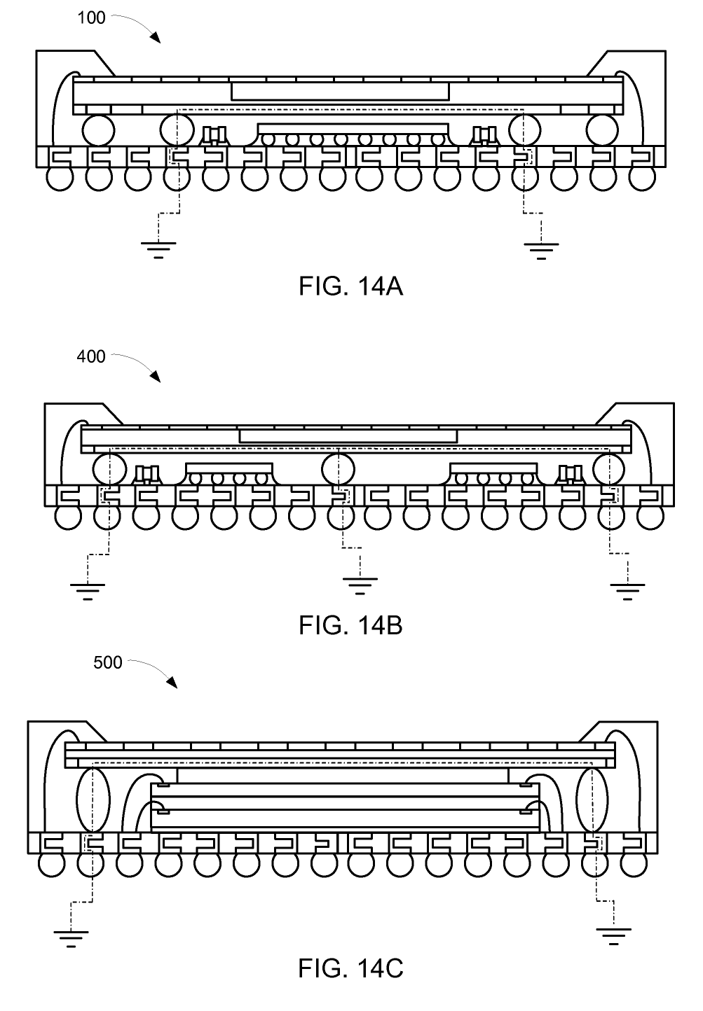

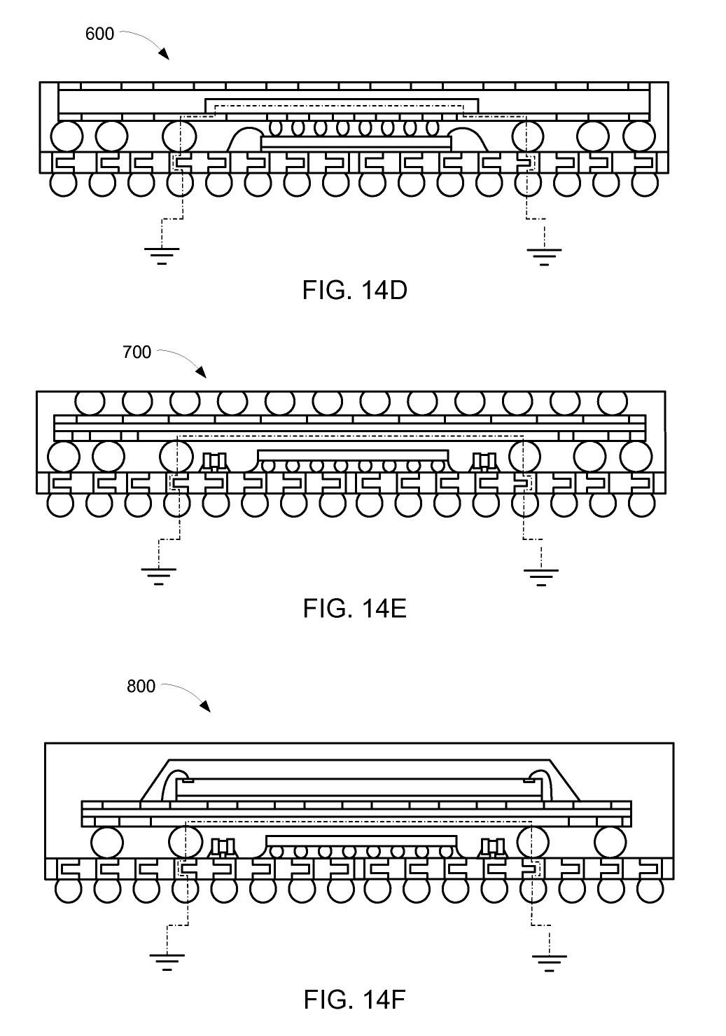

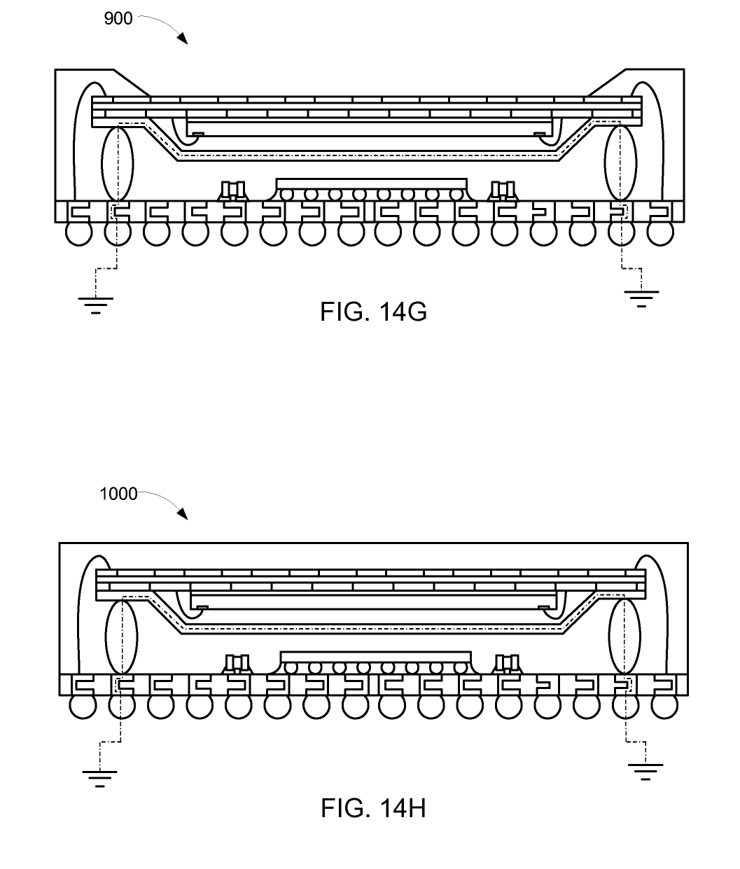

Referring now to FIG. 14A, therein is shown the integrated circuit packaging system 100 of FIG. 1 in the same embodiment and in the same configuration as described supra.

Referring now to FIG. 14B, therein is shown the integrated circuit packaging system 400 of FIG. 4 in the same embodiment and in the same configuration as described supra.

Referring now to FIG. 14C, therein is shown the integrated circuit packaging system 500 of FIG. 5 in the same embodiment and in the same configuration as described supra.

Referring now to FIG. 14D, therein is shown the integrated circuit packaging system 600 of FIG. 6 in the same embodiment and in the same configuration as described supra.

Referring now to FIG. 14E, therein is shown the integrated circuit packaging system 700 of FIG. 7 in the same embodiment and in the same configuration as described supra.

Referring now to FIG. 14F, therein is shown the integrated circuit packaging system 800 of FIG. 8 in the same embodiment and in the same configuration as described supra.

Referring now to FIG. 14G, therein is shown the integrated circuit packaging system 900 of FIG. 9 in the same embodiment and in the same configuration as described supra.

Referring now to FIG. 14H, therein is shown the integrated circuit packaging system 1000 of FIG. 10 in the same embodiment and in the same configuration as described supra.

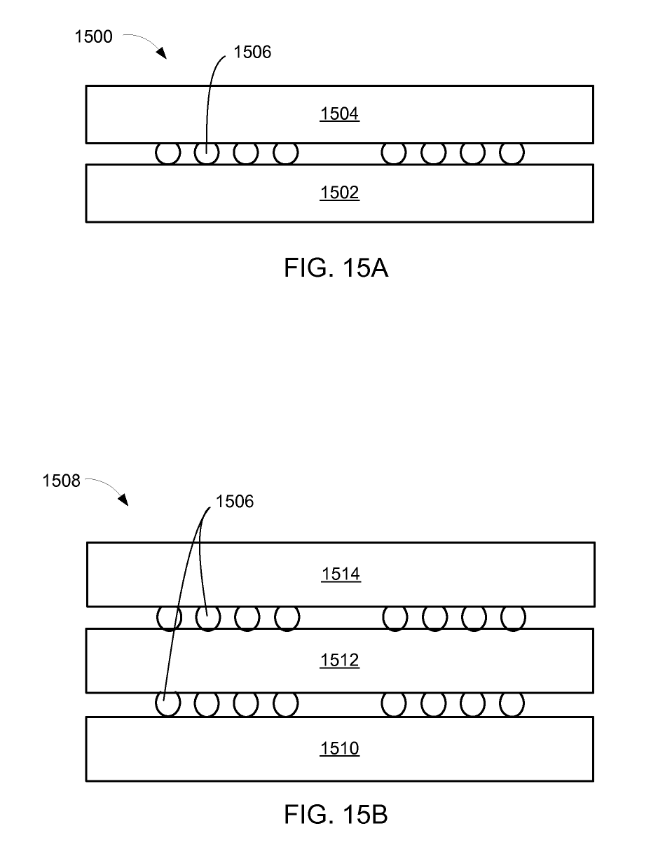

Referring now to FIG. 15A, therein is shown a diagram 1500 of a further embodiment of the present invention. The diagram 1500 is shown having any one of the integrated circuit packaging systems from FIGS. 14A-H in a block 1502 with any one of the external electric components from FIGS. 13A-E in a block 1504 and mounted above the block 1502. The block 1504 is shown connected to the block 1502 with interconnects such as solder bumps 1506.

Referring now to FIG. 15B, therein is shown a diagram 1508 of a further embodiment of the present invention. The diagram 1508 is shown having any one of the external electric components from FIGS. 13A-E in a block 1510 with any one of the integrated circuit packaging systems from FIGS. 14A-H in a block 1512 and mounted above the block 1510. Mounted above the block 1512 is any one of the external electric components from FIGS. 13A-E in a block 1514. The block 1514 is connected to the block 1512 with the solder bumps 1506. The block 1512 is connected to the block 1510 with the solder bumps 1506.

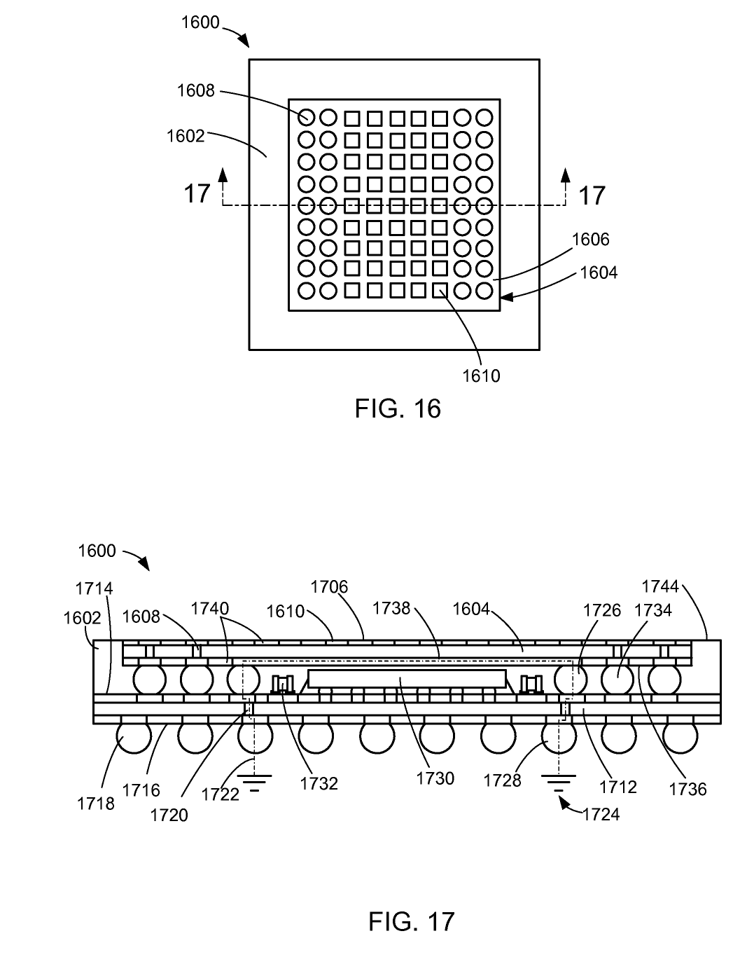

Referring now to FIG. 16, therein is shown a top view of an integrated circuit packaging system 1600 in a further embodiment of the present invention. The top view depicts an encapsulation 1602, such as an encapsulation formed from an epoxy molding compound or the encapsulation 102 of FIG. 1.

A silicon interposer 1604, such as a silicon die, an activated silicon die or a through silicon via (TSV) having a silicon interposer first side 1606 can be exposed from the encapsulation 1602. Vias 1608, such as conductive channels or conductive plugs, can be exposed at the silicon interposer first side 1606. Contact pads 1610, such as bond pads or contact terminals, can be exposed at the silicon interposer first side 1606.

For illustrative purposes, the integrated circuit packaging system 100 is shown with the vias 1608 and the contact pads 1610 as separate element, although it is understood that the integrated circuit packaging system 100 can be formed with a different configuration. For example, the contact pads 1610 can represent exposed portions of the vias 1608.

Referring now to FIG. 17, therein is shown a cross-sectional view of the integrated circuit packaging system 1600 along line segment 17-17 of FIG. 16. The cross-sectional view depicts a substrate 1712, such as the substrate 202 of FIG. 2. The substrate 1712 can have a substrate first side 1714 and a substrate second side 1716. External interconnects 1718, such as solder balls or the solder bumps 204 of FIG. 2, can be attached to the substrate second side 1716.

The substrate 1712 can include shielding channels 1720, such as the substrate interconnects 208 of FIG. 2. The shielding channels 1720 can be part of a shielding structure 1722, such as an electromagnetic interference shielding structure or the grounding path 219 of FIG. 2. The shielding structure 1722 is depicted by the “dot-dash-dash-dot” line. The shielding channels 1720 can traverse through the substrate 1712 between the substrate first side 1714 and the substrate second side 1716. The shielding structure 1722 is not under the substrate 1712.

First shielding interconnects 1726, such as solder balls, solder bumps or the internal interconnects 210 of FIG. 2, can be attached to the shielding channels 1720 on the substrate first side 1714. The shielding channels 1720 can be connected to ground 1724 by second shielding interconnects 1728, such as solder balls or the external interconnects 206 of FIG. 2. The second shielding interconnects 1728 can be attached to the shielding channels 1720 on the substrate second side 1716. The first shielding interconnects 1726 and the second shielding interconnects 1728 can be a part of the shielding structure 1722.

An integrated circuit 1730, such integrated circuit die or a flip-chip, can be mounted over the substrate first side 1714. The integrated circuit 1730 can face the substrate first side 1714. The integrated circuit 1730 can be between the first shielding interconnects 1726.

Internal devices 1732, such as passive components, can be mount over the substrate first side 1714 between the first shielding interconnects 1726 and the integrated circuit 1730. Internal interconnects 1734, such as solder balls or the third internal interconnects 222 of FIG. 2, can be mounted over the substrate first side 1714.

The silicon interposer 1604 can have a silicon interposer second side 1736. The silicon interposer 1604 can be mounted over the substrate first side 1714, the integrated circuit 1730, and the internal devices 1732.

The silicon interposer 1604 can have an integral-conductive-shield 1738, such as a copper sheet or coating or the integral-conductive-shield 214 of FIG. 2, along a portion of the silicon interposer second side 1736. The integral-conductive-shield 1738 is integral to the silicon interposer 1604 because the integral-conductive-shield 1738 is formed along the silicon interposer second side 1736. The integral-conductive-shield 1738 can be formed during formation of the silicon interposer 1604. The integral-conductive-shield 1738 can be a part of the shielding structure 1722. The integral-conductive-shield 1738 can face the integrated circuit 1730.

The integral-conductive-shield 1738 can be formed to have different configurations. For example, the integral-conductive-shield 1738 can be formed to have the configuration as shown in FIG. 3A, FIG. 3B, FIG. 3C, or FIG. 3D.

The integral-conductive-shield 1738 can be connected to the first shielding interconnects 1726. The shielding structure 1722, can be formed through the second shielding interconnects 1728, the shielding channels 1720, the first shielding interconnects 1726, and the integral-conductive-shield 1738. The shielding structure 1722 can be over the integrated circuit 1730 and along the vertical sides of the integrated circuit 1730. The shielding structure 1722 is not formed along the plane of the substrate 1712 under integrated circuit 1730.

The vias 1608 can traverse through the silicon interposer 1604 between the silicon interposer first side 1606 and the silicon interposer second side 1736. The vias 1608 can be exposed at the silicon interposer second side 1736. The vias 1608 exposed at the silicon interposer second side 1736 can be connected to the internal interconnects 1734. An insulation coating (not shown), such as an oxide coating or a dielectric liner, can be between the vias 1608 and adjacent portions of the silicon interposer 1604.

A redistribution layer 1740, such as a conductive metal layer or a metal trace embedded in or surrounded by insulation, can be along the silicon interposer first side 1606 and the silicon interposer second side 1736. The redistribution layer 1740 can have one or more metal layers (not shown). The redistribution layer 1740 can be exposed at the silicon interposer first side 1606 to form the contact pads 1610.

The redistribution layer 1740 that is along the silicon interposer second side 1736 is separate from the integral-conductive-shield 1738 and is not a part of the shielding structure 1722. The integral-conductive shield 1738 can be formed with the same or similar process as to form the redistribution layer 1740.

The encapsulation 1602 can be formed over the substrate first side 1714, around the silicon interposer 1604, and covering the internal interconnects 1734, the first shielding interconnects 1726, the internal device 1732, and the integrated circuit 1730. An encapsulation top side 1744 can be planar with the silicon interposer first side 1606.

It has been discovered that the present invention provides an integrated circuit packaging system improved performance and lower profile. The silicon interposer having integral-conductive-shield improves performance by providing electromagnetic shielding of sensitive components within the integrated circuit packaging system. The silicon interposer can represent a functional active device resulting in a higher density of active circuitry in combination with the integrated circuit. The higher density provides a lower profile. The integral-conductive-shield mitigates or eliminates the electromagnetic interference (EMI) between the silicon interposer and the integrated circuit or the internal devices.

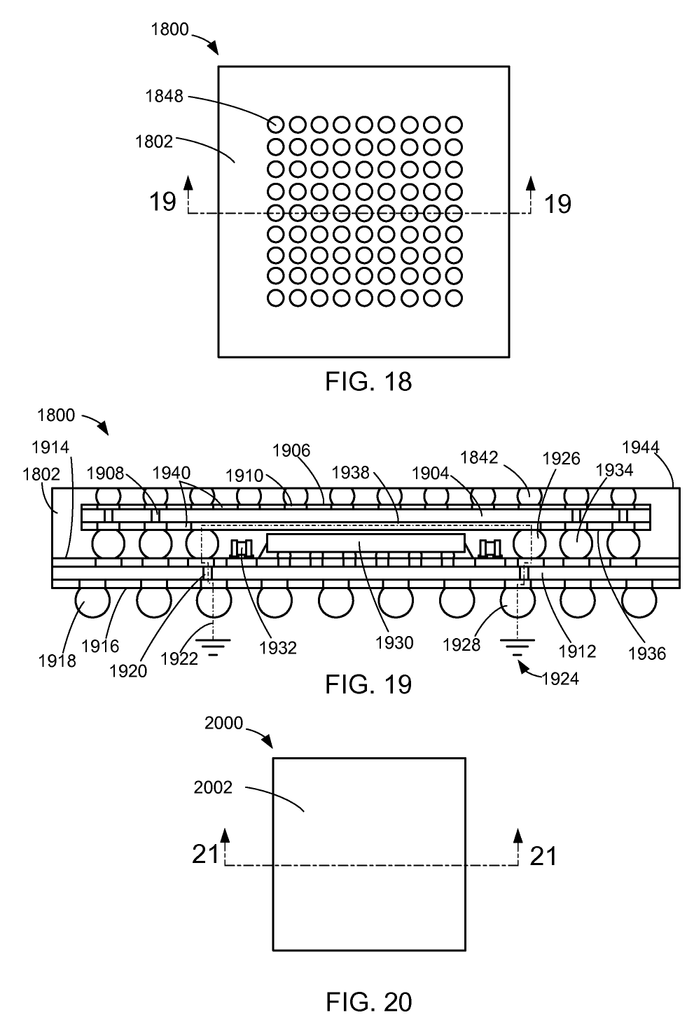

Referring now to FIG. 18, therein is shown a top view of an integrated circuit packaging system 1800 in a further embodiment of the present invention. The top view depicts embedded interconnects 1842, such as solder balls, solder bumps, or conductive posts, exposed from an encapsulation 1802, such as an encapsulation formed from an epoxy molding compound or the encapsulation 102 of FIG. 1. The embedded interconnects 1842 can be used to connect additional devices (not shown) mounted over the integrated circuit packaging system 1800.

Referring now to FIG. 19, therein is shown a cross-sectional view of the integrated circuit packaging system 1800 along line segment 19-19 of FIG. 18. The cross-sectional view depicts a substrate 1912, such as the substrate 202 of FIG. 2. The substrate 1912 can have a substrate first side 1914 and a substrate second side 1916. External interconnects 1918, such as solder balls or the solder bumps 204 of FIG. 2, can be attached to the substrate second side 1916.

The substrate 1912 can include shielding channels 1920, such as the substrate interconnects 208 of FIG. 2. The shielding channels 1920 can be part of a shielding structure 1922, such as an electromagnetic interference shielding structure or the grounding path 219 of FIG. 2. The shielding structure 1922 is depicted by the “dot-dash-dash-dot” line. The shielding channels 1920 can traverse through the substrate 1912 between the substrate first side 1914 and the substrate second side 1916.

First shielding interconnects 1926, such as solder balls, solder bumps or the internal interconnects 210 of FIG. 2, can be attached to the shielding channels 1920 on the substrate first side 1914. The shielding channels 1920 can be connected to ground 1924 by second shielding interconnects 1928, such as solder balls or the external interconnects 206 of FIG. 2. The second shielding interconnects 1928 can be connected to the shielding channels 1920 on the substrate second side 1916. The first shielding interconnects 1926 and the second shielding interconnects 1928 can be a part of the shielding structure 1922.

An integrated circuit 1930, such integrated circuit die or a flip-chip, can be mounted over the substrate first side 1914. The integrated circuit 1930 can face the substrate first side 1914. The integrated circuit 1930 can be between the first shielding interconnects 1926.

Internal devices 1932, such as passive components, can be mount over the substrate first side 1914 between the first shielding interconnects 1926 and the integrated circuit 1930. Internal interconnects 1934, such as solder balls or the third internal interconnects 222 of FIG. 2, can be mounted over the substrate first side 1914.

A silicon interposer 1904, such as a bare silicon die, an activated silicon die, or a through silicon via (TSV), can be mounted over the substrate first side 1914, the integrated circuit 1930, and the internal devices 1932. The silicon interposer 1904 can have a silicon interposer first side 1906 and a silicon interposer second side 1936.

The silicon interposer 1904 can have an integral-conductive-shield 1938, such as a copper sheet or coating or the integral-conductive-shield 214 of FIG. 2, along a portion of the silicon interposer second side 1936. The integral-conductive-shield 1938 is integral to the silicon interposer 1904 because the integral-conductive-shield 1938 is formed along the silicon interposer second side 1936. The integral-conductive-shield 1938 can be formed during formation of the silicon interposer 1904. The integral-conductive-shield 1938 can face the integrated circuit 1930.

The integral-conductive-shield 1938 can be formed to have different configurations. For example, the integral-conductive-shield 1938 can be formed to have the configuration as shown in FIG. 3A, FIG. 3B, FIG. 3C, or FIG. 3D.

The integral-conductive-shield 1938 can be connected to the first shielding interconnects 1926. The shielding structure 1922, can be formed through the second shielding interconnects 1928, the shielding channels 1920, the first shielding interconnects 1926, and the integral-conductive-shield 1938. The shielding structure 1922 can be over the integrated circuit 1930 and along the vertical sides of the integrated circuit 1930. The shielding structure 1922 is not formed along the plane of the substrate 1912 under integrated circuit 1930.

Vias 1908, such as conductive channels or conductive plugs, can traverse through the silicon interposer 1904 between the silicon interposer first side 1906 and the silicon interposer second side 1936. The vias 1908 can be exposed at the silicon interposer first side 1906 and the silicon interposer second side 1936. The vias 1908 exposed at the silicon interposer second side 1936 can be connected to the internal interconnects 1934. An insulation coating (not shown), such as an oxide coating or a dielectric liner, can be between the vias 1908 and adjacent portions of the silicon interposer 1904.

A redistribution layer 1940, such as a conductive metal layer or a metal trace embedded in or surrounded by insulation, can be along the silicon interposer first side 1906 and the silicon interposer second side 1936. The redistribution layer 1940 can have one or more metal layers (not shown). The redistribution layer 1940 that is along the silicon interposer second side 1936 is separate from the integral-conductive-shield 1938 and is not a part of the shielding structure 1922.

The redistribution layer 1940 can be exposed at the silicon interposer first side 1906 to form contact pads 1910. The embedded interconnects 1842 can be connected to the contact pads 1910 and the vias 1908 exposed at the silicon interposer first side 1906. The integral-conductive shield 1938 can be formed with the same or similar process as to form the redistribution layer 1940.

The encapsulation 1802 can be formed over the substrate first side 1914, around the embedded interconnects 1842, covering the internal interconnects 1934, the first shielding interconnects 1926, the internal device 1932, the integrated circuit 1930, and the silicon interposer 1904. The embedded interconnects 1842 can be exposed at an encapsulation top side 1944. The embedded interconnects 1842 can be co-planar with the encapsulation top side 1944.

Referring now to FIG. 20, therein is shown a top view of an integrated circuit packaging system 2000 in a further embodiment of the present invention. The top view depicts an encapsulation 2002, such as an encapsulation formed from an epoxy molding compound or the encapsulation 102 of FIG. 1.

For illustrative purposes, the integrated circuit package system 2000 is shown with the encapsulation 2002 having a square geometric configuration, although it is understood that the encapsulation 2002 can have a different geometric configuration. For example, the integrated circuit package system 2000 can have a rectangular configuration.

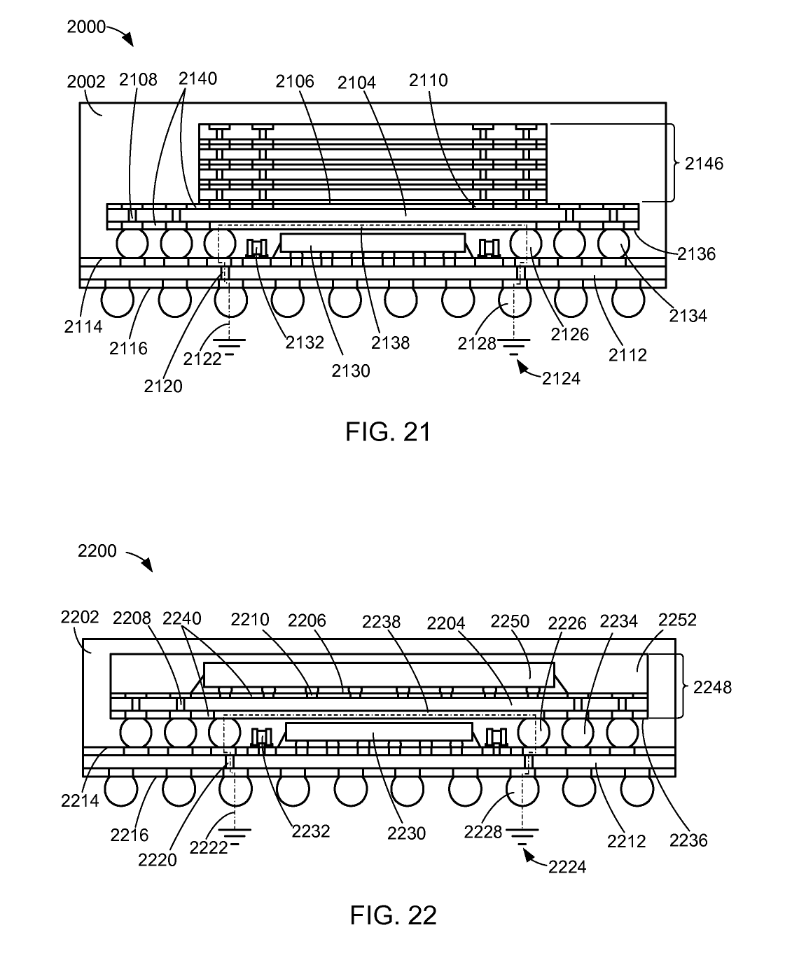

Referring now to FIG. 21, therein is shown a cross-sectional view of the integrated circuit packaging system 2000 along line segment 21-21 of FIG. 20. The cross-sectional view depicts a substrate 2112, such as the substrate 202 of FIG. 2. The substrate 2112 can have a substrate first side 2114 and a substrate second side 2116. External interconnects 2118, such as solder balls or the solder bumps 204 of FIG. 2, can be attached to the substrate second side 2116.

The substrate 2112 can include shielding channels 2120, such as the substrate interconnects 208 of FIG. 2. The shielding channels 2120 can be part of a shielding structure 2122, such as an electromagnetic interference shielding structure or the grounding path 219 of FIG. 2. The shielding structure 2122 is depicted by the “dot-dash-dash-dot” line. The shielding channels 2120 can traverse through the substrate 2112 between the substrate first side 2114 and the substrate second side 2116.

First shielding interconnects 2126, such as solder balls, solder bumps or the internal interconnects 210 of FIG. 2, can be attached to the shielding channels 2120 on the substrate first side 2114. The shielding channels 2120 can be connected to ground 2124 by second shielding interconnects 2128, such as solder balls or the external interconnects 206 of FIG. 2. The second shielding interconnects 2128 can be attached to the shielding channels 2120 on the substrate second side 2116. The first shielding interconnects 2126 and the second shielding interconnects 2128 can be a part of the shielding structure 2122.

An integrated circuit 2130, such integrated circuit die or a flip-chip, can be mounted over the substrate first side 2114. The integrated circuit 2130 can face the substrate first side 2114. The integrated circuit 2130 can be between the first shielding interconnects 2126.

Internal devices 2132, such as passive components, can be mount over the substrate first side 2114 between the first shielding interconnects 2126 and the integrated circuit 2130. Internal interconnects 2134, such as solder balls or the third internal interconnects 222 of FIG. 2, can be mounted over the substrate first side 2114.

A silicon interposer 2104, such as a bare silicon die or an activated silicon die, can be mounted over substrate first side 2114, the integrated circuit 2130, and the internal device 2132. The silicon interposer 2104 can have a silicon interposer first side 2106 and a silicon interposer second side 2136.

The silicon interposer 2104 can have an integral-conductive-shield 2138, such as a copper sheet or coating or the integral-conductive-shield 214 of FIG. 2, along a portion of the silicon interposer second side 2136. The integral-conductive-shield 2138 is integral to the silicon interposer 2104 because the integral-conductive-shield 2138 is formed along the silicon interposer second side 2136. The integral-conductive-shield 2138 can be formed during formation of the silicon interposer 2104. The integral-conductive-shield 2138 can be a part of the shielding structure 2122. The integral-conductive-shield 2138 can face the integrated circuit 2130.

The integral-conductive-shield 2138 can be formed to have different configurations. For example, the integral-conductive-shield 2138 can be formed to have the configuration as shown in FIG. 3A, FIG. 3B, FIG. 3C, or FIG. 3D.

The integral-conductive-shield 2138 can be connected to the first shielding interconnects 2126. The shielding structure 2122, can be formed through the second shielding interconnects 2128, the shielding channels 2120, the first shielding interconnects 2126, and the integral-conductive-shield 2138. The shielding structure 2122 can be over the integrated circuit 2130 and along the vertical sides of the integrated circuit 2130. The shielding structure 2122 is not formed along the plane of the substrate 2112 under integrated circuit 2130.

Vias 2108, such as conductive channels or conductive plugs, can traverse through the silicon interposer 2104 between the silicon interposer first side 2106 and the silicon interposer second side 2136. The vias 2108 can be exposed at the silicon interposer first side 2106 and the silicon interposer second side 2136. The vias 2108 exposed at the silicon interposer second side 2136 can be connected to the internal interconnects 2134. An insulation coating (not shown), such as an oxide coating or a dielectric liner, can be between the vias 2108 and adjacent portions of the silicon interposer 2104.

A redistribution layer 2140, such as a conductive metal layer or a metal trace embedded in or surrounded by insulation, can be along the silicon interposer first side 2106 and the silicon interposer second side 2136. The redistribution layer 2140 can have one or more metal layers (not shown). The redistribution layer 2140 can be exposed at the silicon interposer first side 2106 to form contact pads 2110.

The redistribution layer 2140 that is along the silicon interposer second side 2136 is separate from the integral-conductive-shield 2138 and is not a part of the shielding structure 2122. The integral-conductive shield 2138 can be formed with the same or similar process as to form the redistribution layer 2140.

An integrated circuit die stack 2146, such as a stack of one or more through-silicon-via dice or integrated circuit dice, can be mounted over the silicon interposer 2104. The integrated circuit die stack 2146 can be bonded with various known bonding methods.

For illustrative purposes, the integrated circuit packaging system 2000 is shown with the integrated circuit die stack 2146 mounted over the silicon interposer 2104 and connected to the contact pads 2110, although it is understood that the integrated circuit die stack 2146 can be mounted differently. For example, the integrated circuit die stack 2146 can be mounted over the silicon interposer 2104 and connected to the contact pads 2110, the vias 2108, or a combination thereof.

The encapsulation 2002 can be formed over the substrate first side 2114 and covering the silicon interposer 2104, the internal interconnects 2134, the first shielding interconnects 2126, the internal device 2132, and the integrated circuit 2130. The encapsulation 2002 can also be formed over the integrated circuit die stack 2146.

Referring now to FIG. 22, therein is shown a cross-sectional view of an integrated circuit packaging system 2200 along line segment 21-21 of FIG. 20 in a further embodiment of the present invention. The cross-sectional view depicts a substrate 2212, such as the substrate 202 of FIG. 2. The substrate 2212 can have a substrate first side 2214 and a substrate second side 2216. External interconnects 2218, such as solder balls or the solder bumps 204 of FIG. 2, can be attached to the substrate second side 2216.

The substrate 2212 can include shielding channels 2220, such as the substrate interconnects 208 of FIG. 2. The shielding channels 2220 can be part of a shielding structure 2222, such as an electromagnetic interference shielding structure or the grounding path 219 of FIG. 2. The shielding structure 2222 is depicted by the “dot-dash-dash-dot” line. The shielding channels 2220 can traverse through the substrate 2212 between the substrate first side 2214 and the substrate second side 2216.

First shielding interconnects 2226, such as solder balls, solder bumps or the internal interconnects 210 of FIG. 2, can be attached to the shielding channels 2220 on the substrate first side 2214. The shielding channels 2220 can be attached to ground 2224 by second shielding interconnects 2228, such as solder balls or the external interconnects 206 of FIG. 2. The second shielding interconnects 2228 can be connected to the shielding channels 2220 on the substrate second side 2216. The first shielding interconnects 2226 and the second shielding interconnects 2228 can be a part of the shielding structure 2222.

An integrated circuit 2230, such integrated circuit die or a flip-chip, can be mounted over the substrate first side 2214. The integrated circuit 2230 can face the substrate first side 2214. The integrated circuit 2230 can be between the first shielding interconnects 2226.

Internal devices 2232, such as passive components, can be mount over the substrate first side 2214 between the first shielding interconnects 2226 and the integrated circuit 2230. Internal interconnects 2234, such as solder balls or the third internal interconnects 222 of FIG. 2, can be mounted over the substrate first side 2214.

An interstack module 2248 can be mounted over the substrate first side 2214, the integrated circuit 2230, and the internal device 2232. The interstack module can include a silicon interposer 2204, such as a bare silicon die or an activated silicon die, having a silicon interposer first side 2206 and a silicon interposer second side 2236. The interstack module 2248 can include an integrated circuit device 2250, such as an integrated circuit die or a flip-chip, mounted over the silicon interposer first side 2206. The interstack module 2248 can include an interstack module encapsulation 2252, such as an encapsulation formed from an epoxy molding compound. The interstack module encapsulation 2252 can be over the silicon interposer first side 2206 and can cover the integrated circuit device 2250. The interstack module encapsulation 2252 can be optional.

The silicon interposer 2204 can have an integral-conductive-shield 2238, such as a copper sheet or coating or the integral-conductive-shield 214 of FIG. 2, along a portion of the silicon interposer second side 2236. The integral-conductive-shield 2238 is integral to the silicon interposer 2204 because the integral-conductive-shield 2238 is formed along the silicon interposer second side 2236. The integral-conductive-shield 2238 can be formed during formation of the silicon interposer 2204. The integral-conductive-shield 2238 can be a part of the shielding structure 2222. The integral-conductive-shield 2238 can face the integrated circuit 2230.

The integral-conductive-shield 2238 can be formed to have different configurations. For example, the integral-conductive-shield 2238 can be formed to have the configuration as shown in FIG. 3A, FIG. 3B, FIG. 3C, or FIG. 3D.

The integral-conductive-shield 2238 can be connected to the first shielding interconnects 2226. The shielding structure 2222, can be formed through the second shielding interconnects 2228, the shielding channels 2220, the first shielding interconnects 2226, and the integral-conductive-shield 2238. The shielding structure 2222 can be over the integrated circuit 2230 and along the vertical sides of the integrated circuit 2230. The shielding structure 2222 is not formed along the plane of the substrate 2212 under integrated circuit 2230.

Vias 2208, such as conductive channels or conductive plugs, can traverse through the silicon interposer 2204 between the silicon interposer first side 2206 and the silicon interposer second side 2236. The vias 2208 can be exposed at the silicon interposer first side 2206 and the silicon interposer second side 2236. The vias 2208 exposed at the silicon interposer second side 2236 can be connected to the internal interconnects 2234. An insulation coating (not shown), such as an oxide coating or a dielectric liner, can be between the vias 2208 and adjacent portions of the silicon interposer 2204.

A redistribution layer 2240, such as a conductive metal layer or a metal trace embedded in or surrounded by insulation, can be along the silicon interposer first side 2206 and the silicon interposer second side 2236. The redistribution layer 2240 can have one or more metal layers (not shown). The redistribution layer 2240 that is along the silicon interposer second side 2236 is separate from the integral-conductive-shield 2238 and is not a part of the shielding structure 2222.

The redistribution layer 2240 can be exposed at the silicon interposer first side 2206 to form contact pads 2210. The integral-conductive shield 2238 can be formed with the same or similar process as to form the redistribution layer 2240.

A package encapsulation 2202, such as an encapsulation formed from an epoxy molding compound or the encapsulation 102 of FIG. 1, can be formed over the substrate first side 2214 and covering the silicon interposer 2204, the internal interconnects 2234, the first shielding interconnects 2226, the internal device 2232, and the integrated circuit 2230. The encapsulation can also be formed over the interstack module 2248.

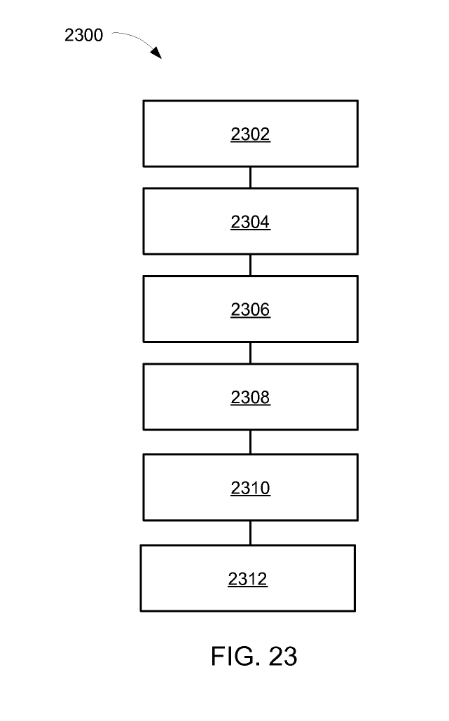

Referring now to FIG. 23, therein is shown a flow chart of a method 2300 of manufacture of an integrated circuit packaging system in a further embodiment of the present invention. The system includes providing a substrate having a shielding channel through a substrate first side and a substrate second side in a block 2302; mounting a first shielding interconnect to the shielding channel in block 2304; mounting an integrated circuit over the substrate and adjacent to the first shielding interconnect in a block 2306; attaching a silicon interposer, having an integral-conductive-shield and a via, to the first shielding interconnect with the integral-conductive-shield over the integrated circuit in a block 2308; grounding the shield channel at the substrate second side in a block 2310; and forming an encapsulation over the substrate covering the integrated circuit and the first shielding interconnect in a block 2312.

Thus, it has been discovered that the integral-conductive-shield system of the present invention furnishes important and heretofore unknown and unavailable solutions, capabilities, and functional aspects for integrated circuit packaging system configurations. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
providing a substrate having a shielding channel through a substrate first side and a substrate second side;
mounting a first shielding interconnect to the shielding channel;
mounting an integrated circuit over the substrate and adjacent to the first shielding interconnect;
attaching a silicon interposer, having an integral-conductive-shield and a via, to the first shielding interconnect with the integral-conductive-shield over the integrated circuit;
grounding the shielding channel at the substrate second side; and
forming an encapsulation over the substrate covering the integrated circuit and the first shielding interconnect.

2. The method as claimed in claim 1 wherein forming the encapsulation includes forming the encapsulation planar with a silicon interposer first side that is exposed from the encapsulation.

3. The method as claimed in claim 1 wherein the attaching the silicon interposer includes attaching the integral-conductive-shield to the first shielding interconnect.

4. The method as claimed in claim 1 further comprising:
attaching an embedded interconnect to the silicon interposer; and
wherein forming the encapsulation includes forming the encapsulation around and exposing the embedded interconnect.

5. The method as claimed in claim 1 further comprising mounting an internal device over the substrate between the integrated circuit and the first shielding interconnect.

6. A method of manufacture of an integrated circuit packaging system comprising:
providing a substrate having a shielding channel through a substrate first side and a substrate second side;
mounting a first shielding interconnect to the shielding channel;
mounting an integrated circuit over the substrate and facing the substrate first side with the integrated circuit adjacent to the first shielding interconnect;
mounting an internal interconnect over the substrate first side;
attaching a silicon interposer, having an integral-conductive-shield, a contact pad, and a via, to the first shielding interconnect and the internal interconnect with the integral-conductive-shield over the integrated circuit;
mounting a second shielding interconnect to the shielding channel along the substrate second side;
grounding the second shielding interconnect at the substrate second side; and
forming an encapsulation over the substrate covering the integrated circuit and the first shielding interconnect.

7. The method as claimed in claim 6 further comprising:
mounting an integrated circuit die stack over the silicon interposer; and
wherein forming the encapsulation includes forming the encapsulation over the integrated circuit die stack.

8. The method as claimed in claim 6 further comprising:
mounting an integrated circuit device over the silicon interposer; and
wherein forming the encapsulation includes forming the encapsulation over the integrated circuit device.

9. The method as claimed in claim 6 wherein mounting the second shielding interconnect includes attaching an external interconnect to the substrate second side.

10. The method as claimed in claim 6 wherein mounting the integrated circuit over the substrate includes mounting a flip-chip.

11. An integrated circuit packaging system comprising:
a substrate having a shielding channel through a substrate first side and a substrate second side with the shielding channel grounded at the substrate second side;
a first shielding interconnect mounted to the shielding channel;
an integrated circuit mounted over the substrate and adjacent to the first shielding interconnect;
a silicon interposer, having an integral-conductive-shield and a via, attached to the first shielding interconnect with the integral-conductive-shield over the integrated circuit; and
an encapsulation over the substrate covering the integrated circuit and the first shielding interconnect.

12. The system as claimed in claim 11 wherein the encapsulation is planar with a silicon interposer first side that is exposed from the encapsulation.

13. The system as claimed in claim 11 wherein the silicon interposer includes the integral-conductive-shield attached to the first shielding interconnect.

14. The system as claimed in claim 11 further comprising:
an embedded interconnect attached to the silicon interposer; and
wherein the encapsulation is around and exposes the embedded interconnect.

15. The system as claimed in claim 11 further comprising an internal device mounted over the substrate between the integrated circuit and the first shielding interconnect.

16. The system as claimed in claim 11 further comprising:
a contact pad exposed at a silicon interposer first side;
an internal interconnect mounted over the substrate first side; and
wherein:
the silicon interposer is attached to the internal interconnect; and
the integral-conductive-shield is along a silicon interposer second side.

17. The system as claimed in claim 16 further comprising:
an integrated circuit die stack mounted over the silicon interposer; and
wherein the encapsulation is over the integrated circuit die stack.

18. The system as claimed in claim 16 further comprising:
an integrated circuit device mounted over the silicon interposer; and
wherein the encapsulation is over the integrated circuit device.

19. The system as claimed in claim 16 further comprising an external interconnect attached to the substrate second side.

20. The system as claimed in claim 16 wherein the integrated circuit mounted over the substrate includes a flip-chip.
